(19) United States
(12) Patent Application Publication
(10) Pub. No.: US 2009/0032977 A1
(43) Pub. Date: Feb. 5, 2009

(54) SEMICONDUCTOR DEVICE

(76) Inventor: Tsunemori Yamaguchi, Kyoto (JP)

Correspondence Address: RABIN & Berdo, PC, 1101 14TH STREET, NW, SUITE 500, WASHINGTON, DC, 20005, US

(21) Appl. No.: 11/910,912

(22) PCT Filed: Mar. 28, 2006
(86) PCT No.: PCT/JP2006/306326

§ 371 Date: Oct. 5, 2007

(30) Foreign Application Priority Data
Aug. 4, 2005 (JP) 2005-112392

(51) Int. Cl. H01L 23/28

(52) U.S. Cl. 257/787; 257/E23.116

(57) ABSTRACT

The present invention is disclosed a semiconductor device which enables to easily perform a visual inspection of the bonded state between a lead and a land of wiring board. This semiconductor device comprises a lead in which at least a part of the lower surface thereof is exposed form the lower surface of the encapsulation resin and the end face thereof is exposed from the lateral surface of the encapsulation resin. The lower surface of the lead is provided with a groove which reaches the outer end edge of the lead.

### TECHNICAL FIELD

The present invention relates to a semiconductor device fabricated by resin-encapsulating a semiconductor chip, more specifically, a surface-mounted semiconductor device.

### BACKGROUND ART

Recently, in order to realize high-density mounting of semiconductor devices on a wiring board, a surface-mount package which can be surface-mounted on the wiring board has been frequently used. As this surface-mount package, for example, there is known a so-called Non-leaded Package such as QFN (Quad Flat Non-leaded Package) or SON (Small Outlined Non-leaded Package) in which extension of a lead from a resin package is eliminated and a lead (outer lead) is exposed to the lower surface of the resin package.

In such a package, semiconductor chips, etc., are resin-encapsulated on a lead frame, and thereafter, the semiconductor chips, etc., are cut off from the frame portion of the lead frame.

More specifically, the lead frame is fabricated by applying precision press working to a band-shaped copper plate and then applying solder plating onto the surface thereof, and unit portions corresponding to the respective semiconductor devices are continuously provided in the longitudinal direction of the copper plate. A unit portion corresponding to one semiconductor device includes, for example, as shown in FIG. 6, a rectangular die pad 101 for supporting a semiconductor chip, a frame portion 102 surrounding this die pad 101, and a plurality of leads 103 disposed on both sides of the longitudinal direction of the copper plate with respect to the die pad 101 at generally even intervals in a direction orthogonal to the longitudinal direction. The die pad 101 is bonded to the frame portion 102 via a joint (not shown). Each lead 103 is formed into a long shape which has a base end portion joined to the frame portion 102 and extends toward the die pad 101. Then, a semiconductor chip is die-bonded onto the die pad 101, terminals of this semiconductor chip and the upper surfaces of the leads 103 are connected by bonding wires 105 (see FIG. 7), and then the inside of an encapsulated area 104 shown by the alternate long and two short dashes line is encapsulated in an encapsulation resin 106 (see FIG. 7). Thereafter, the leads 103 are cut along the cutting lines 107 shown as the dashed lines, and the die pad 101 and the respective leads 103 are cut off from the frame portion 102, whereby a non-leaded package (SON) is obtained.

A portion of the lead 103 to be encapsulated in the encapsulation resin 106 serves as an inner lead to be electrically connected to the semiconductor chip via the bonding wire 105. The lower surface (a surface opposite to the surface to which the bonding wire 105 is connected) 108 of the lead 103 is exposed from the lower surface of the encapsulation resin 106, as shown in FIG. 7, and serves as an outer lead to be solder-bonded to a land (wiring pattern) 110 on the wiring board 109. Onto the land 110, cream solder 111 is applied, and by bonding the lower surface 108 of the lead 103 to the land 110 via the cream solder 111, surface mounting of the semiconductor device on the wiring board 109 is realized.
Patent Document 1: Japanese Unexamined Patent Publication No. 2001-156233

### DISCLOSURE OF THE INVENTION

### Problems to be Solved by the Invention

However, the cream solder 111 on the land 110 closely adheres only to a portion applied with solder plating of the surface of the lead 103. That is, in the state of the lead frame, solder plating is applied to the entire surface of the lead 103. However, the lead 103 is cut along the cutting line 107, whereby to the end face (cut surface along the cutting line 107) of the lead 103, a copper plate forming the base of the lead frame is exposed. Therefore, the cream solder 111 on the land 110 does not closely adhere to the end face of the lead 103.

A visual inspection (conforming/nonconforming check) of the bonding (soldering) between the lead 103 and the land 110 is performed based on, as a criterion, whether a bulge of the cream solder 111, that is, solder fillet is formed on the end face side of the lead 103. Therefore, if the solder fillet is not formed on the end face side of the lead 103 due to the failure of close adhesion of the cream solder 111 to the end face of the lead 103, the visual inspection for the bonded state between the lead 103 and the land 110 becomes difficult.

Therefore, an object of the present invention is to provide a semiconductor device which enables to easily perform a visual inspection of the bonded state between a lead and a land of the wiring board.

### Means for Solving the Problems

A semiconductor device according to an aspect of the present invention includes a semiconductor chip, an encapsulation resin which encapsulates this semiconductor chip, and a lead which is electrically connected to the semiconductor chip in the encapsulation resin, and is encapsulated in the encapsulation resin together with the semiconductor chip so that at least a part of the lower surface of the lead is exposed from the lower surface of the encapsulation resin and an end face of the lead is exposed from the lateral surface of the encapsulation resin. In a portion exposed from the encapsulation resin of the lower surface of the lead, a groove reaching the outer end face of the lead is formed.

With this construction, in the portion exposed from the encapsulation resin of the lead, a groove reaching the outer end face of the lead is formed. Therefore, at the time of surface-mounting of a semiconductor device on a wiring board, when the lower surface exposed from the encapsulation resin of the lead is bonded to cream solder applied onto a land of the wiring board, the cream solder intrudes into the inside of the groove formed on the lower surface of the lead. Thereby, the cream solder bulges to the outer end face side of the lead, and a so-called solder fillet is formed on the outer end face side of the lead. Therefore, a visual inspection of the bonded (soldered) state between the lead and the land of the wiring board can be easily performed.

It is preferable that solder plating is applied onto the inner surface of the groove.

With this construction, the solder plating is applied onto the inner surface of the groove, so that the cream solder that has intruded inside the groove exerts excellent adhesion to the inner surface of the groove. Therefore, the bonding strength of the lead to the land can be increased. In addition, reliable electrical connection between the lead and the land can be realized.

It is preferable that the lead has a weir formed around the groove except the end face side thereof and preventing the encapsulation resin from intruding into the groove.

With this construction, a weir is formed around the groove, so that when the semiconductor device is assembled, the encapsulation resin can be prevented from intruding into the groove, and the groove can be prevented from being filled with the encapsulation resin. When the semiconductor device is mounted, the cream solder on the land can be reliably made to intrude into the groove, thereby a solder fillet can be reliably formed.

The above-described or other objects, features, and effects of the present invention will be made apparent by the description of the embodiment given below with reference to the accompanying drawings.

### BRIEF DESCRIPTION OF THE DRAWINGS

FIG. 1 is a schematic sectional view showing a construction of a semiconductor device (lead cut type) according to an embodiment of the present invention;

FIG. 2 is a bottom view of the semiconductor device of FIG. 1;

FIG. 3 is a perspective view of one corner of the semiconductor device of FIG. 1;

FIG. 4 is a schematic sectional view showing a mounted state of the semiconductor device of FIG. 1;

FIG. 5 is a schematic sectional view showing a construction of a semiconductor device (singulation type) according to another embodiment of the present invention;

FIG. 6 is a plan view showing a construction of a conventional lead frame; and

FIG. 7 is a schematic sectional view showing a mounted state of a semiconductor device using the lead frame of FIG. 6.

### BEST MODE FOR CARRYING OUT THE INVENTION

Hereinafter, an embodiment of the present invention will be described in detail with reference to the accompanying drawings.

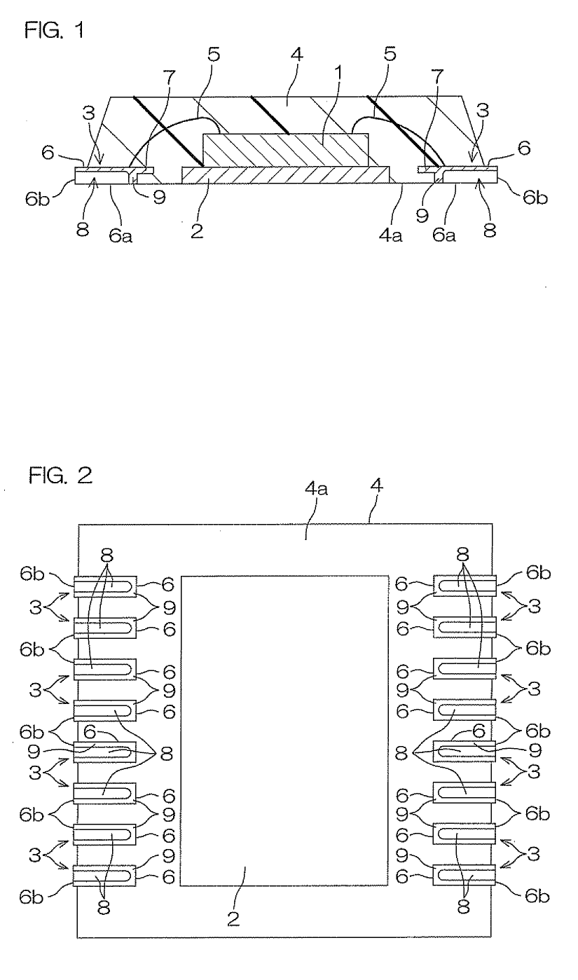

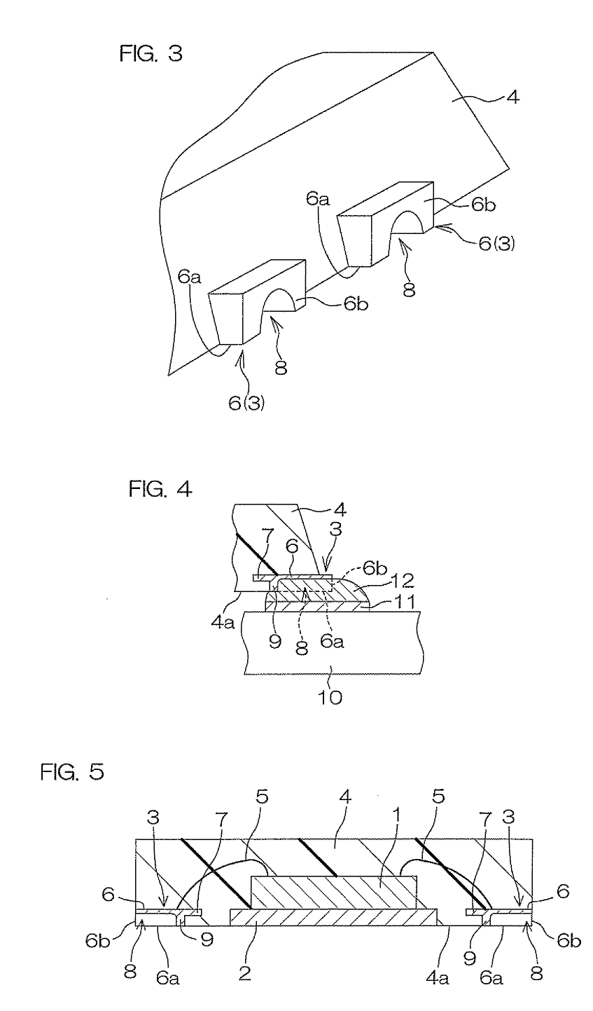

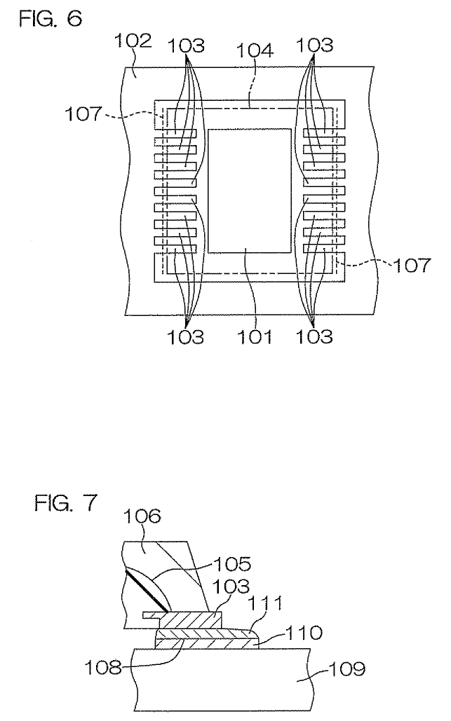

FIG. 1 is a schematic sectional view showing a construction of a semiconductor device according to an embodiment of the present invention. FIG. 2 is a bottom view (showing a surface to be bonded to a wiring board) of the semiconductor device of FIG. 1, and FIG. 3 is a perspective view of one corner of the semiconductor device.

This semiconductor device is a semiconductor device to which a lead cut type SON (Small Outlined Non-leaded Package) is applied, and includes a semiconductor chip 1, a die pad 2 which supports the semiconductor chip 1, a plurality of leads 3 to be electrically connected to the semiconductor chip 1, and an encapsulation resin 4 in a generally truncated four-sided pyramid shape for encapsulating these elements.

The semiconductor chip 1 is die-bonded onto the die pad 2 so that its surface on the side on which the functional elements are formed (device forming surface) faces upward. On the surface of the semiconductor chip 1, a plurality of pads (not shown) are formed by exposing a part of a wiring layer from a surface protecting film formed on the top surface. Each pad is connected to the lead 3 by a bonding wire 5.

The die pad 2 is formed in a rectangular shape in a plan view. The lower surface of the die pad 2 is exposed from a lower surface 4a of the encapsulation resin 4.

The leads 3 are provided in the same number (8 each in this embodiment) on one end edge side of the die pad 2 and the other end edge side opposite to the one end edge side, and on each side, the leads are aligned at predetermined intervals in a direction along the one end edge and a lower end edge.

Each lead 3 is formed in a rectangular shape in a plan view elongated in a direction orthogonal to the alignment direction of the leads 3 (in a direction facing the die pad 2). Each lead 3 integrally includes a main body 6 and a stopper 7 formed by crushing the end portion on the die pad 2 side from the lower surface side.

The main body 6 has a lower surface 6a exposed from the lower surface 4a of the encapsulation resin 4, and an outer end face 6b exposed from the lateral surface of the encapsulation resin 4. The lower surface 6a of the main body 6 exposed from the lower surface 4a of the encapsulation resin 4 functions as an outer lead to be solder-bonded to a land (wiring pattern) 11 on a wiring board 10 described later. A groove 8 reaching the outer end face 6b of the main body 6 is formed on the lower surface 6a of the main body 6. A portion of the main body 6 to be encapsulated in the encapsulation resin 4 serves as an inner lead, and the bonding wire 5 is connected to the upper surface thereof.

The stopper 7 is formed to be thinner than the main body 6, and near the upper surface of the main body 6, it projects toward the die pad 2 and also projets from the both sides of the lead 3 in a direction orthogonal to the longitudinal direction of the lead 3. In a state where the lead 3 is resin-encapsulated together with the semiconductor chip 1, the encapsulation resin 4 intrudes under the stopper 7, so that the lead 3 is prevented from coming off from the encapsulation resin 4.

When this semiconductor device is assembled, in the state of the lead frame formed by coupling the die pad 2 and the leads 3 to a common frame portion (not shown), the semiconductor chip 1 is die-bonded onto the die pad 2, and the pad of the semiconductor chip 1 and the upper surfaces of the leads 3 are connected by bonding wires 5, and then the semiconductor chip 1, the die pad 2, the leads 3, and the bonding wires 5 are encapsulated in the encapsulation resin 4. At this time, a portion 9 generally formed in a U-shape in a bottom view around the groove 8 of each lead 3 functions as a weir for preventing the encapsulation resin 4 from intruding into the groove 8. Thereafter, the leads 3 are cut off along the lateral surface of the encapsulation resin 4 (package), and the die pad 2 and the respective leads 3 are cut off from the frame portion of the lead frame. Thereby, a semiconductor device of a lead cut type SON is obtained.

The lead frame is fabricated, for example, by forming the die pad 2, the leads 3, and the frame portion through applying precision press working to a copper plate with a plate thickness of 0.2 mm, and then forming the stoppers 7 through crushing the lower surfaces of the leads 3, forming the grooves 8 through etching, and solder-plating the entire surface thereof. Therefore, in the state of the lead frame, solder plating layers are formed on the entire surfaces of the leads 3. However, after the die pad 2 and the respective leads 3 are cut off from the frame portion of the lead frame (after a piece of the semiconductor is cut out), due to cutting of the respective leads 3, the copper plate serving as the base of the lead frame is exposed to the outer end faces 6b (cut surfaces of the leads 3) of the main bodies 6 of the respective leads 3.

FIG. 4 is a schematic sectional view showing a mounted state of this semiconductor device. This semiconductor device is surface-mounted so that the lower surface thereof on which the leads 3 are exposed faces the surface of the wiring board 10, that is, the surface on which the lands (wiring pattern) 11 are formed.

Onto the land 11, cream solder 12 is applied. When this semiconductor device is mounted on the surface of the wiring board 10, the lower surface 6a of the main body 6 of the lead 3 is bonded to the land 11 via this cream solder 12.

A solder plating layer is formed on the side surface of the main body 6 of the lead 3, so that when the lower surface 6a of the main body 6 is bonded to the cream solder 12 on the land 11, the cream solder 12 closely adheres to the side surface of the main body 6 so as to creep up thereonto. A groove 8 is formed on the lower surface 6a of the main body 6 of the lead 3, so that when the lower surface 6a of the main body 6 is bonded to the cream solder 12 on the land 11, the cream solder 12 intrudes into the inside of the groove 8. Thereby, the cream solder 12 bulges to the outer end face 6b side of the main body 6 of the lead 3, whereby a so-called solder fillet is formed on the outer end face 6b side of the main body 6 of the lead 3. Therefore, a visual inspection of the bonded (soldered) state between the lead 3 and the land 11 can be easily performed.

In addition, a solder plating layer is also formed on the inner surface of the groove 8, so that the cream solder 12 that has intruded into the inside of the groove 8 exerts excellent adhesion to the inner surface of the groove 8. Therefore, the bonding strength of the lead 3 to the land 11 can be increased. In addition, reliable electrical connection between the lead 3 and the land 11 can be realized.

Furthermore, a weir 9 generally in a U-shape in a bottom view is formed around the groove 8, so that when the semiconductor device is assembled, the encapsulation resin 4 can be prevented from intruding into the groove 8, and the groove 8 can be prevented from being filled with the encapsulation resin 4. Therefore, at the time of mounting of the semiconductor device, the cream solder 12 on the land 11 can be reliably made to intrude into the inside of the groove 8, and a solder fillet can be reliably formed.

An embodiment of the present invention is described above, however, the present invention can also be carried out by other embodiments. For example, in the above-described embodiment, a semiconductor device having a lead cut type SON is used as an example, however, the present invention is also applicable to a semiconductor device in which the outer end face 6b of the main body 6 of the lead 3 is made flush with the lateral surface of the encapsulation resin 4, that is, a semiconductor device having a so-called singulation type SON, as shown in FIG. 5. Without limiting to the SON, the present invention is also applicable to, for example, a semiconductor device having a QFN (Quad Flat Non-leaded Package).

In the above-described embodiment, the groove 8 is formed on the lower surface 6a of the main body 6 of the lead 3 by means of etching. However, a method other than etching, for example, laser machining can also be used to form the groove 8.

In addition, various design variations can be made within the scope of the matters described in the Claims.

What is claimed is:

1. A semiconductor device comprising:
a semiconductor chip;
an encapsulation resin which encapsulates the semiconductor chip; and
a lead which is electrically connected to the semiconductor chip in the encapsulation resin, and is encapsulated in the encapsulation resin together with the semiconductor chip so that at least a part of a lower surface of the lead is exposed from a lower surface of the encapsulation resin and an end face of the lead is exposed from a lateral surface of the encapsulation resin, wherein
in a portion exposed from the encapsulation resin, of the lower surface of the lead, a groove reaching an outer end face of the lead is formed.

2. The semiconductor device according to claim 1, wherein solder plating is applied to an inner surface of the groove.

3. The semiconductor device according to claim 1, wherein the lead includes a weir which is formed around the groove except the side of the end face thereof and prevents the encapsulation resin from intruding into the groove.
